(19) United States
(12) Patent Application Publication
(10) Pub. No.: US 2005/0200387 A1
(43) Pub. Date: Sep. 15, 2005

(54) Method for RIAA correction without capacitors in correcting circuits

(75) Inventor: Alexander Y. Sokolov, Moscow (RU)

Correspondence Address: JOSHUA D. ISENBERG, 204 CASTRO LANE, FREMONT, CA, 94539, US

(73) Assignee: Outsource Technologies, Inc., San Rafael, CA (US)

(21) Appl. No.: 10/898,013

(22) Filed: Jul. 22, 2004

(30) Foreign Application Priority Data
Feb. 18, 2004 (RU) 2004104602

(51) Int. Cl. H03K 5/153

(52) U.S. Cl. 327/86

(57) ABSTRACT

RIAA correction of electrical signals without the use of capacitors in a correction circuit is disclosed. A transformer is used with two or more windings, including at least two secondary windings are loaded on resistive circuits to form frequency correction. Additional inductors are installed in series with each of the secondary windings or with just one of the secondary windings.

### CROSS REFERENCE TO RELATED APPLICATION

This application claims priority from Russian Patent Application 2004104602, to Alexander Sokolov, filed Feb. 18, 2004, the disclosures of which are incorporated herein by reference.

This application is related to commonly assigned co-pending U.S. patent application Ser. No. ______ (Attorney Docket No.: OST-002) to Alexander Sokolov entitled “METHOD FOR RIAA CORRECTION OF AUDIO SIGNAL WITH USE OF TRANSFORMER”, which is filed concurrently herewith. This application is also related to commonly assigned co-pending U.S. patent application Ser. No. (Attorney Docket No.: OST-003) to Alexander Sokolov entitled “METHOD FOR RIAA CORRECTION OF AUDIO SIGNAL WITH USE OF TRANSFORMER AND CAPACITOR”, which is filed concurrently herewith.

### FIELD OF INVENTION

The invention relates to electronic equipment, hi-fi and hi-end audio systems. It can be used in electronic pre-amplifiers for phono players (RIAA-correctors).

### 1. BACKGROUND

Audio signal recording on a phono disk is based on the well-known Recording Industry Association of America (RIAA) correction procedure. According to this procedure the amplitude of an electrical signal recorded on disk depends on the signal frequency. Such correction is carried out to improve the dynamic range of the signal. When the disk is played back, the electrical signal coming from the pickup cartridge to the output power amplifier and later to the speaker has to pass through a pre-amplifier with additional frequency correction, in which the reverse correction procedure is applied.

Mathematically expressed the frequency correction transmission function from the input to output of the pre-amplifier has the form:
Uout/Uin=K0*(1+i*w*b)/((1+i*w*b1)*(1+i*w*b2)),
where Uout and Uin are signal amplitudes at the output and input, respectively,

Ko is frequency independent amplification factor,

w=2*π*f,

f is the signal frequency,

b=318, b1=75, b2=3180 are time constants, expressed in milliseconds,

i is complex unity. There are many different realizations of RIAA-correctors. Among them one can find transistor, solid state and vacuum tube circuits.

Usually capacitors are implemented in such pre-amplifiers as the elements featuring frequency-dependent characteristics.

In spite of their simplicity of use, capacitors introduce disturbances into the signal transmitted. This factor degrades the audio characteristics of the pre-amplifier. The electrical parameters of capacitors depend essentially on the dielectrics used, the foil and the winding method. As a result capacitors possess such undesirable features as non-linearity, inductance, energetic losses during the electrical signal transmission, etc. Experts often notice the dependence of the sound on the capacitors types, the coarse sounding of cheap capacitors in the upper register of the sound signal, sticky and dim sound.

### 2. BRIEF DESCROTION OF THE DRAWINGS

FIG. 1 illustrates a schematic diagram of a RIAA circuit according to a first embodiment of the invention.

FIG. 2 illustrates schematic diagram of a RIAA circuit according to a second embodiment of the invention.

FIG. 3 illustrates an electrical schematic of a RIAA pre-amplifier according to alternative embodiments of the present invention.

### 3. DETAILED DESCRIPTION

According to a first embodiment, it is proposed to use a transformer with two or more secondary windings as a RIAA correction circuit in the pre-amplifier, with at least two of secondary windings loaded on resistive circuits to form frequency correction, being different in that additional inductors are installed consequently with each of the above mentioned windings.

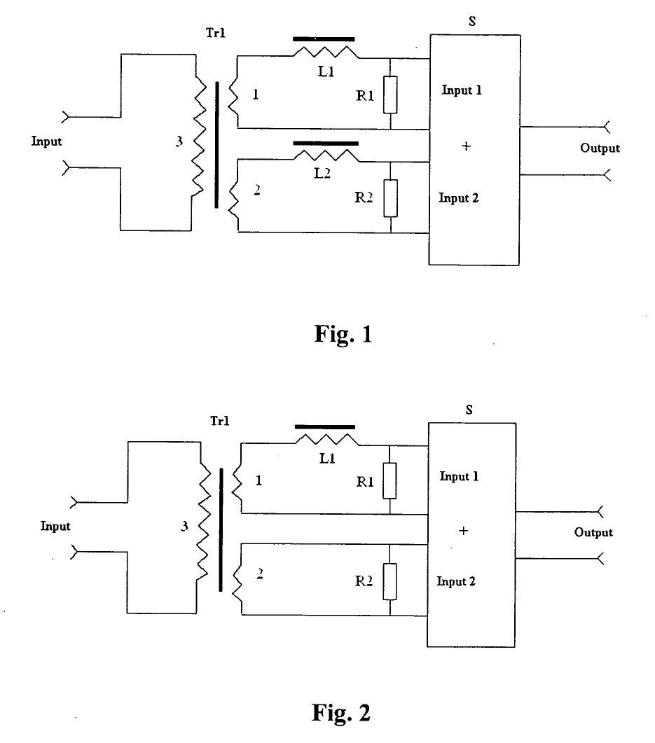

A schematic illustrating the first embodiment is shown in FIG. 1. In this figure the additional element, S, is shown which performs the addition of two signals from the resistors R1 and R2, with signal weights S1 and S2, respectively.

Assume that the transformer has a number of turns N1 in the primary winding 3 (connected to the input), and N2 and N3 turns in the secondary windings 1 and 2, respectively.

The signal transmission functions K1 and K2 from the input to resistors R1 and R2 will be equal to
K1=(N1/N3)/(1+i*w*t1),
K2=(N2/N3)/(1+i*w*t2),
where t1=L1/R1, t2=L2/R2.

After summation with the weights S1 and S2 the final signal transmission function will be equal

K=K1*S1+K2*S2=((N1 *S1+N2*S2)/N3)*(1+i*w*t)/((1+i*w*t1)*(1+i*w*t2)), where t=(N2*S2*t1+N1*S1*t2)/(N1*S1+N2*S2).

Thus, this will coincide with the RIAA correction transmission function if

L1/R1=b1=75 microseconds,
L2/R2=b2=3180 microseconds,
(S1*N1*b2+S2*N2*b1)/(S1*N1+S2*N2)=b=318 microseconds.
   In particular, if S1=S2, the last condition will hold if approximately N2/N1≈11,8.

According to a second embodiment, it is proposed to use a transformer with two or more secondary windings as the RIAA correction circuit in the pre-amplifier, with at least two of secondary windings loaded on resistive circuits to form frequency correction, being different in that only one additional inductor is installed consequently with the one of above mentioned windings.

A schematic illustrating a circuit for use in the second embodiment is shown in FIG. 2. This schematic is similar to that in FIG. 1 and is different only in that the second inductor is not used.

The principle is based on the usage of internal leakage inductance of the second winding. The leakage inductance is the usual feature of the transformer and is well described elsewhere. The leakage inductance depends on the number of turns in the windings, the geometry of the winding and the transformer. Typically the leakage inductance has small value Ls. This inductance introduces small addition to the value of inductance in the circuit. However, because the value b1 is also small (75 microseconds), if a very small value of resistor R2 is selected the leakage inductor itself can have enough value to be used to form the characteristic time b1,
Ls/R2=75 microseconds.

In this case the second additional inductor will be unnecessary.

According to a third embodiment, it is proposed to use a RIAA correction circuit according as in the first or second embodiments, being different in that the transformation factor from the primary to at least one of the secondary windings is less than unity.

The transformation factors from the primary to each of the secondary windings are equal to N1/N3 and N2/N3 according to FIGS. 1 and 2.

The advantage of this method is that small inductance values for the inductors can be selected. This reduces the size and the cost of the inductors.

The values of the resistors and inductors cannot have any arbitrary small values, because this will affect the adjustment with the output internal resistance (impedance) of the signal source. However, reducing the transformation factor X times will increase the input resistance (impedance) of the circuit considered (the value of the resistances recalculated to the primary winding) in the square of X, while the amplitude will decrease only in X. Given the value of the output resistance of the signal source the reduction of the transformation factor in X will reduce the values of inductors in the factor of X squared.

Thus, at the cost of some decrease of the value of output signal the cost of inductors can be essentially reduced.

According to a fourth embodiment, it is proposed to use the RIAA correction circuit according to the first or second embodiment, being different in that the inductors are made without magnetic cores.

If the inductors have relatively small values, they can be made as the windings without any additional magnetic materials. In this case inductors will perform like ideal ones which value is independent of the value of the current.

According to a fifth embodiment, it is proposed to use the RIAA correction circuit according to the first or second embodiment, being different in that the primary winding is electrically connected to a vacuum tube.

Vacuum tubes are used usually in high-end audio systems because vacuum tubes produce outstanding sound valued by many amateurs. A vacuum tube can have a short and fast decreasing spectrum of harmonics, which is one of the reasons of good sound.

According to a sixth embodiment, it is proposed to use the RIAA correction circuit according to the first or second embodiments, being different in that the correction circuit is used in the remaining circuit without capacitors, except only the possible capacitors used in constant voltage supply units.

The usage of the capacitors is undesirable also in other parts of the scheme. Because the invention is based on the transformer, all capacitors can be eliminated completely, with the possible exception of capacitors used in constant voltage supply units.

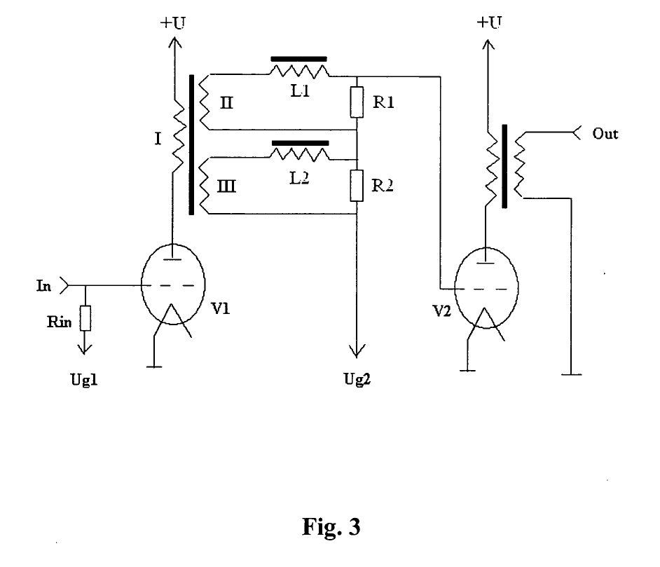

FIG. 3 shows a schematic illustrating examples of the fifth and sixth embodiments.

FIG. 3 shows the full schematic of the pre-amplifier. A first vacuum triode V1 is connected to a transformer having a primary I and two secondary windings II and III. The summation of the signals from two resistors R1, R2, connected to the secondary windings II and III, is carried out directly on the resistors R1, R2. The two secondary windings II, III of the first transformer are connected to each other at one end of the winding. A second vacuum triode V2 is connected to a second transformer that provides an output (Out). The grids of the triodes V1, V2 are connected to grid voltage supplies Ug1 and Ug2 respectively through input resistor Rin and one end of the second winding III of the first transformer via resistors R1, R2. The pre-amplifier of FIG. 3 doesn't use any of capacitors, with the possible exception of those which can be used in constant voltage supply units, e.g., voltage supplies Ug1 and Ug2. The second vacuum triode with the regular wide-band transformer is used for final amplification of the signal after RIAA correction circuit.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. In the claims that follow, the indefinite article “A”, or “An” refers to a quantity of one or more of the item following the article, except where expressly stated otherwise. The appended claims are not to be interpreted as including means-plus-function or step-plus-function 1 imitations, unless such a limitation is explicitly recited in a given claim using the phrase “means for” or “step for.”

1. A method of RIAA correction of electrical signal without the use of capacitors in a correction circuit, comprising using a transformer with two or more windings, wherein at least two secondary windings are loaded on resistive circuits to form frequency correction, being different in that additional inductors are installed in series with each of the secondary windings.

2. A method of RIAA correction of electrical signal without the use of capacitors in a correction circuit is claimed, comprising using a transformer with two or more windings including a primary winding and two or more secondary windings, wherein at least two of the secondary windings are loaded on resistive circuits to form frequency correction, being different in that only one additional inductor is installed in series with the one of the secondary windings.

3. A method of RIAA correction according to claim 1 or 2, wherein a transformation factor from a primary winding to at least one the secondary windings is less than unity.

4. A method of RIAA correction according to claim 1 or 2 is claimed, wherein at least one of the inductors is made without the use of a magnetic core.

5. A method of RIAA correction according to claim 1 or 2 is claimed, being different in that the primary winding is electrically connected to a vacuum tube.

6. A method of RIAA correction according to claim 1 or 2 is claimed, wherein the correction circuit is used without capacitors, with the possible exception of capacitors used in one or more constant voltage supply units.

7. A circuit for RIAA correction, comprising:
a transformer with two or more windings, including a primary winding and at least two secondary windings that are loaded on resistive circuits for frequency correction, and
inductors installed in series with at least one of the secondary windings.

8. The circuit of claim 7 wherein inductors are installed in series with each of the secondary windings.

9. The circuit of claim 7 or 8 wherein a transformation factor from the primary winding to at least one the secondary windings is less than unity.

10. The circuit of claim 7 or 8 wherein at least one of the inductors is made without the use of a magnetic core.

11. The circuit of claim 7 or 8, further comprising a vacuum triode having an anode that is electrically connected to the primary winding.

12. The circuit of claim 11, further comprising a second vacuum triode having a grid that is electrically connected to one of the secondary windings at a point between an inductor and a resistor that are in series with the secondary winding.

13. The circuit of claim 12, further comprising a second transformer connected to the second vacuum triode, the second transformer providing an output.

14. The circuit of claim 7 or 8 wherein the correction circuit uses no capacitors, with the possible exception of capacitors used in one or more constant voltage supply units.
